(19) United States
(12) Patent Application Publication
(10) Pub. No.: US 2026/0293310 A1
(43) Pub. Date: Sep. 24, 2026

(54) DISPLAY SUBSTRATE AND DISPLAY DEVICE

(71) Applicants: Chongqing BOE Display Technology Co., Ltd., Chongqing (CN); BOE Technology Group Co., Ltd., Beijing (CN); Beijing BOE Technology Development Co., Ltd., Beijing (CN)

(72) Inventors: Faming JIANG, Beijing (CN); Tianlong ZHAO, Beijing (CN); Wentao WANG, Beijing (CN); Weixing GONG, Beijing (CN); Lingling WANG, Beijing (CN); Liang ZHOU, Beijing (CN); Dawei SHI, Beijing (CN)

(21) Appl. No.: 19/479,786

(22) PCT Filed: Apr. 16, 2024
(86) PCT No.: PCT/CN2024/087988

§ 371 Date: Oct. 29, 2025

(30) Foreign Application Priority Data
May 25, 2023 (CN) 202310601751.8

(51) Int. Cl. H10D 86/40; H10D 86/60

(52) U.S. Cl. CPC H10D 86/441; H10D 86/421; H10D 86/60

(57) ABSTRACT

The present disclosure provides a display substrate and a display device. The display substrate includes a base substrate, a first semiconductor layer and a first conductive layer stacked on the base substrate; the first conductive layer includes a plurality of conductive signal lines extending in a first direction and arranged in a second direction; and conductive signal lines each include a first end electrically connected to a driving circuit and a second end; the first semiconductor layer includes at least one first semiconductor structure extending along the second direction; and an orthographic projection of the first semiconductor structure on the base substrate overlaps an orthographic projection of the second end of the at least one conductive signal line on the base substrate; and the display substrate further includes an electrostatic discharge device on the base substrate and electrically connected to the second end of the conductive signal line.

### TECHNICAL FIELD

The present disclosure relates to the field of display technology, in particular to a display substrate and a display device.

### BACKGROUND

A display device includes various circuits, a pixel driving circuit is configured to provide a voltage to a first electrode of each light-emitting device in the display device, and includes a semiconductor layer and a conductive layer, the semiconductor layer is used for forming an active layer of a transistor, the conductive layer is used for forming a conductive line, and a large amount of static electricity easily generated at a tail end of the conductive line breaks down the active layer, so that the circuit cannot operate normally.

### SUMMARY

The present disclosure is directed to at least one of the technical problems in the prior art, and provides a display substrate and a display device.

In a first aspect, the embodiment of the present disclosure provides a display substrate, including a base substrate, a first semiconductor layer and a first conductive layer stacked on the base substrate;

Wherein the first conductive layer includes a plurality of conductive signal lines extending in a first direction and arranged side by side in a second direction; and each conductive signal line includes a first end electrically connected to a driving circuit and a second end;

The first semiconductor layer includes at least one first semiconductor structure extending along the second direction; and an orthographic projection of the first semiconductor structure on the base substrate overlaps with an orthographic projection of the second end of the at least one conductive signal line on the base substrate; and

The display substrate further includes an electrostatic discharge device on the base substrate, and electrically connected to the second end of the conductive signal line, with the orthographic projection of the second end of the conductive signal line at least overlapping with the orthographic projection of the first semiconductor structure on the base substrate.

The electrostatic discharge device and the conductive signal line electrically connected to each other have a one-piece structure.

The electrostatic discharge device includes a patch structure or a meandering line.

The electrostatic discharge device is the patch structure, and a shape of an orthographic projection of the patch structure on the base substrate includes an ellipse.

The electrostatic discharge device is the meandering line, and the meandering line extends away from the second end of the conductive signal line.

The electrostatic discharge element is located in the first semiconductor layer and located on a side of the first semiconductor structure proximal to the second end of the conductive signal line; and an orthographic projection of the electrostatic discharge device on the base substrate overlaps with the orthographic projection of the second end of the conductive signal line on the base substrate.

The first conductive layer is located on a side of the first semiconductor layer away from the base substrate, the display substrate further including a light shielding layer between the first semiconductor layer and the base substrate; the light shielding layer is used as the electrostatic discharge device, and an orthographic projection of the light shielding layer on the base substrate overlaps with the orthographic projection of the second end of the conductive signal line on the base substrate; and

The orthographic projection of the light shielding layer on the base substrate covers an orthographic projection of a first semiconductor structure close to the second end on the base substrate.

The display substrate further includes a second conductive layer located on a side of the first semiconductor layer away from the base substrate, the second conductive layer includes an output terminal of the driving circuit and a first transfer line electrically connected to the output terminal, and the first transfer line is electrically connected to the first end of the conductive signal line through a first connection via.

The second conductive layer includes a redundant first transfer line; and the redundant first transfer line is electrically connected to the second end of the conductive signal line through a second connection via; and

The redundant first transfer line is used as the electrostatic discharge device.

The conductive signal line includes at least one of a scan signal line and a light-emitting control signal line;

The plurality of conductive signal lines include the scan signal line, the driving circuit includes a gate driving circuit, and a first end of one scan signal line is connected to an output terminal of one corresponding first shift register in the gate driving circuit; and

The plurality of conductive signal lines include the light-emitting control signal line, the driving circuit includes a light-emitting control driving circuit, and a first end of one light-emitting control signal line is connected to an output terminal of one corresponding second shift register in the light-emitting control driving circuit.

The display substrate includes a display region and a peripheral region; and the driving circuit includes the gate driving circuit and the light-emitting control driving circuit located in the peripheral region and respectively arranged on two opposite sides of the base substrate in the display region along the first direction.

In a second aspect, the embodiment of the present disclosure provides a display substrate, including a base substrate, a first semiconductor layer and a first conductive layer stacked on the base substrate;

Wherein the first conductive layer includes a plurality of conductive signal lines extending in a first direction and arranged side by side in a second direction; and each conductive signal line includes a first end electrically connected to the driving circuit and a second end;

The first semiconductor layer includes at least one first semiconductor structure extending along the second direction; and an orthographic projection of the first semiconductor structure on the base substrate overlaps with an orthographic projection of the second end of the at least one conductive signal line on the base substrate;

The first conductive layer is located on a side of the first semiconductor layer away from the base substrate, and the display substrate further includes a light shielding layer, severing as an electrostatic discharge device, between the first semiconductor layer and the base substrate, and an orthographic projection of the light shielding layer on the base substrate overlaps with the orthographic projection of the second end of the conductive signal line on the base substrate, and

An orthographic projection of the light shielding layer on the base substrate covers an orthographic projection of the first semiconductor structure close to the second end on the base substrate.

In a third aspect, the embodiment of the present disclosure provides a display substrate, including a base substrate, a first semiconductor layer and a first conductive layer stacked on the base substrate;

Wherein the first conductive layer includes a plurality of conductive signal lines extending in a first direction and arranged side by side in a second direction; and each conductive signal line includes a first end electrically connected to the driving circuit and a second end;

The first semiconductor layer includes at least one first semiconductor structure extending along the second direction; and an orthographic projection of the first semiconductor structure on the base substrate overlaps with an orthographic projection of the second end of the at least one conductive signal line on the base substrate; and

The display substrate further includes an electrostatic discharge device located on the first semiconductor layer and located on a side of the first semiconductor structures closer to the second end of the conductive signal line; an orthographic projection of the electrostatic discharge device on the base substrate overlaps with the orthographic projection of the second end of the conductive signal line on the base substrate, and the electrostatic discharge device is in a floating state.

In a fourth aspect, the embodiment of the present disclosure further provides a display device, which includes the display substrate described in any one of the above embodiments.

### BRIEF DESCRIPTION OF DRAWINGS

FIG. 1 is a schematic diagram of a structure of a driving circuit and a conductive signal line in the prior art.

FIG. 2 is a top view of a display substrate according to an embodiment of the present disclosure.

FIG. 3 is a schematic diagram of a structure of an exemplary pixel circuit.

FIG. 4 is a schematic diagram of a driving timing of the pixel circuit shown in FIG. 3.

FIG. 5 is a cross-sectional view of a display substrate according to an embodiment

FIG. 6 is a schematic diagram of a structure of a patch electrode as an electrostatic discharge device according to an embodiment of the present disclosure.

FIG. 7 is a schematic diagram of a structure of a meandering line (or a winding line) as an electrostatic discharge device according to an embodiment of the present disclosure.

FIG. 8 is a schematic diagram of a structure of a light shielding layer as an electrostatic discharge device according to an embodiment of the present disclosure.

FIG. 9 is a schematic cross-sectional view of a light shielding layer as an electrostatic discharge device according to an embodiment of the present disclosure.

FIG. 10 is a schematic diagram of a structure of a redundant first transfer line as an electrostatic discharge device according to an embodiment of the present disclosure.

FIG. 11 is a schematic cross-sectional view of a redundant first transfer line as an electrostatic discharge device according to an embodiment of the present disclosure.

FIG. 12 is a schematic diagram of a structure of an electrostatic discharge device disposed in a first semiconductor layer according to an embodiment of the present disclosure.

### DETAIL DESCRIPTION OF EMBODIMENTS

In order to enable one of ordinary skill in the art to better understand the technical solutions of the present disclosure, the present disclosure will be described in further detail with reference to the accompanying drawings and the detailed description.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term of “comprising”, “including”, or the like, means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

A display device includes various circuits, a pixel driving circuit is configured to provide a voltage to a first electrode of each light-emitting device in the display device, and includes a semiconductor layer and a conductive layer, the semiconductor layer is used for forming an active layer of a transistor, the conductive layer is used for forming a conductive line, and a large amount of static electricity easily generated at a tail end of the conductive line breaks down the active layer, so that the circuit cannot operate normally.

Taking a wearable display device as an example, the wearable display device has certain limitations in circuit design and related arrangement due to a small volume and size, a gate driving circuit and the light-emitting control driving circuit adopt a single-side design, the gate driving circuit is arranged on one side of the display device, and the light-emitting control driving circuit is arranged on the opposite side. A conductive signal line electrically connected to the gate driving circuit and the light-emitting control driving circuit includes a first end and a second end, the first end is connected to the circuit, the second end is in a floating state and is not connected to any other structure, so that a certain amount of static electricity may be accumulated on the second end, thereby affecting other structures in a display substrate. For example, a semiconductor structure, corresponding to the second end, for forming an active layer of a transistor is broken down.

In view of the above, the present disclosure provides a display substrate, which is provided with an electrostatic discharge device electrically connected to a conductive signal line for discharging static electricity, thereby preventing a semiconductor structure from being broken down, and improving the yield of the display substrate and the reliability of the display substrate in the use.

The display substrate in the present disclosure is further specifically described below with reference to specific embodiments and drawings.

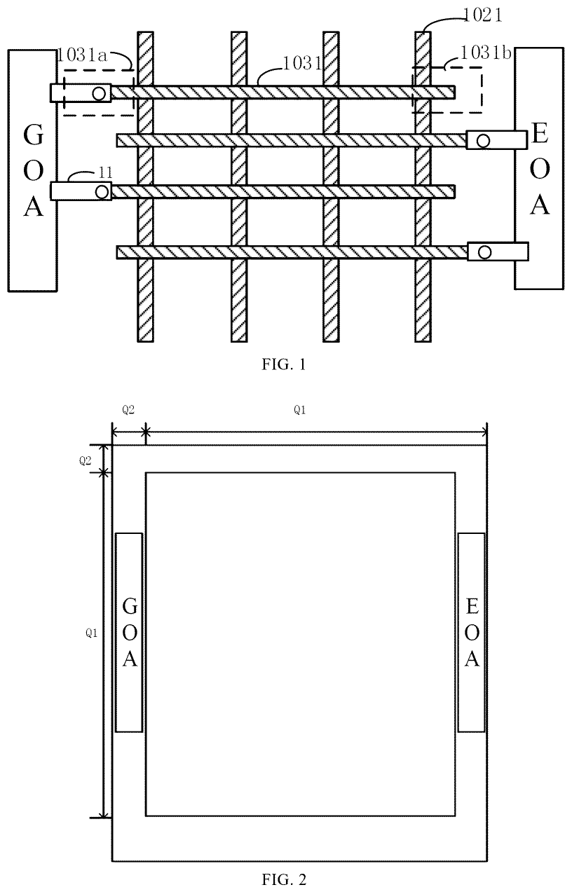

In the embodiment of the present disclosure, FIG. 1 is a schematic diagram of a structure of a driving circuit and a conductive signal line in the prior art. FIG. 2 is a top view of a display substrate according to an embodiment of the present disclosure. As shown in FIGS. 1 and 2, the display substrate is divided into a display region Q1 and a peripheral region Q2, a plurality of pixel units are arranged in an array in the display region Q1, and each pixel unit includes a pixel driving circuit and a light-emitting device. When the driving circuit includes a gate driving circuit and a light-emitting control driving circuit, the gate driving circuit and the light-emitting control driving circuit are located in the peripheral region Q2 and are respectively disposed on two opposite sides of the base substrate 101 in the display region Q1 along a first direction, and an extending direction of the conductive signal line 1031 is the first direction. The gate driving circuit includes a plurality of cascaded first shift registers, each first shift register includes an output terminal connected to a first end 1031a of the conductive signal line, and a second end 1031b of the conductive signal line is in a floating state; the light-emitting control driving circuitincludes a plurality of cascaded second shift registers, each second shift register has an output terminal connected to the first end 1031a of the conductive signal line, and the second end 1031b is in a floating state. Since the second end 1031b is in a floating state, a tip discharge is easily generated at the second end 1031b, which breaks down a conductive structure or a semiconductor structure on other layers of the display substrate.

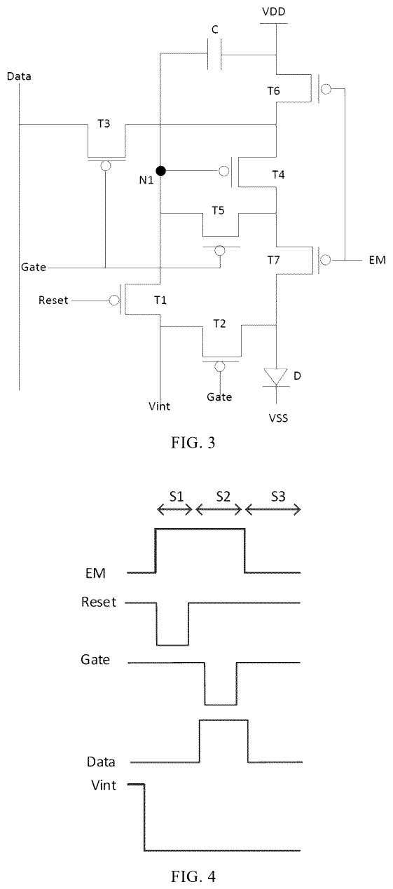

In the embodiment of the present disclosure, FIG. 3 is a schematic diagram of a structure of an exemplary pixel circuit. As shown in FIG. 3, the pixel circuit includes: a first reset transistor T1, a second reset transistor T2, a data writing transistor T3, a driving transistor T4, a storage capacitor C, a threshold compensation transistor T5, a first light-emitting control transistor T6, a second light-emitting control transistor T7, and a light-emitting device D.

Specifically, the first reset transistor Tl has a gate electrode G connected to a reset signal terminal Reset, a source electrode connected to an initialization signal terminal Vint, and a drain electrode connected to a first node N1; the first node N1 is a connection point where the first reset transistor T1, the driving transistor T4, the storage capacitor C, and the threshold compensation transistor T5 are connected to each other. The second reset transistor T2 has a gate electrode G connected to the reset signal terminal Reset, a source electrode connected to the initialization signal terminal Vint, and a drain electrode connected to an anode of the light-emitting device D. The data writing transistor T3 has a gate electrode G connected to a scan signal terminal Gate, a source electrode connected to a data signal terminal Data, and a drain electrode connected to a source electrode of the driving transistor T4. The driving transistor T4 has a gate electrode G connected to the first node N1, the source electrode connected to the drain electrode of the data writing transistor T3 and a drain electrode of the first light-emitting control transistor T6, and a drain electrode connected to a source electrode of the threshold compensating transistor T5 and a source electrode of the second light-emitting control transistor T7. One end of the storage capacitor C is connected to a first power voltage terminal VDD, and the other end of the storage capacitor C is connected to the first node N1. The threshold compensation transistor T5 has a gate electrode G connected to the scan signal terminal Gate, the source electrode connected to the drain electrode of the driving transistor T4, and a drain electrode connected to the first node N1. The first light-emitting control transistor T6 has a gate electrode G connected to a light-emitting control terminal EM, a source electrode connected to the first power voltage terminal VDD, and a drain electrode connected to the source electrode of the driving transistor T4. The second light-emitting control transistor T7 has a gate electrode G connected to the light-emitting control terminal EM, the source electrode connected to the drain electrode of the driving transistor T4, and a drain electrode connected to the anode of the light-emitting device D. The light-emitting device D has an anode connected to the drain electrode of the second light-emitting control transistor T7 and the drain electrode of the second reset transistor T2, and a cathode connected to a second power voltage terminal VSS. The gate driving circuit provides an electric signal to a scan signal terminal through a scan signal line, and the light-emitting control driving circuit provides an electric signal to a light-emitting control terminal through a light-emitting control signal line.

FIG. 4 is a schematic diagram of a driving timing of the pixel circuit shown in FIG. 3. As shown in FIG. 4, the operation process of the pixel circuit includes: a reset stage S1, a data writing stage S2, and a light-emitting stage S3.

In the reset stage S1, a low level signal is input to the reset signal terminal Reset, so that the first reset transistor T1 and the second reset transistor T2 are turned on under the control of the low level signal. An initialization signal (i.e., a low level signal) input to the initialization signal terminal Vint is used to reset the first node N1 and the anode of the light-emitting device D, so that the first node N1 and the anode of the light-emitting device D are restored to a lower potential, thereby avoiding interference of a high level data signal from an immediately previous frame of display picture on the first node N1 and the anode of the light-emitting device D, and preventing the accuracy of the data signal input this time from being affected.

In the data writing stage S2, a low level signal is input to the scan signal terminal Gate, so that the data writing transistor T3 is turned on under the control of the low level signal, a data signal is written to the source electrode of the driving transistor T4, and the storage capacitor C stores the data signal. Meanwhile, the threshold compensation transistor T5 is turned on under the control of the low level signal, the driving transistor T4 is turned on under the control of the data signal stored in the storage capacitor C, so that the gate electrode G and the drain electrode of the driving transistor T4 are connected to each other, and the driving transistor T4 is in a self-saturation state. At this time, the data signal and a threshold voltage of the driving transistor T4 are written into the first node N1, thereby compensating the threshold voltage of the driving transistor T4.

In the light-emitting stage S3, a low level signal is input to a switch control signal terminal EM, so that the first light-emitting control transistor T6 and the second light-emitting control transistor T7 are turned on under the control of the low level signal. The driving transistor T4 may convert a voltage of the first power voltage terminal VDD into a driving current, so that a current loop for the light-emitting device D is formed between the first power voltage terminal VDD and the second power voltage terminal VSS to drive the light-emitting device D to emit light.

The transistors used in the embodiments of the present disclosure may be thin film transistors or field effect transistors or other switching devices with the same characteristics, and the thin film transistors may include oxide semiconductor thin film transistors, amorphous silicon thin film transistors or polysilicon thin film transistors, or the like. Since a source electrode and a drain electrode of the transistor are symmetrical, there is no difference between the source electrode and the drain electrode. In the embodiments of the present disclosure and the following description, in order to distinguish the source electrode and the drain electrode of the transistor from each other, one of the source electrode and the drain electrode is referred to as a first electrode, the other electrode is referred to as a second electrode, and the gate electrode G is referred to as a control electrode. In addition, the transistors may be divided into N type transistors and P type transistors according to the characteristics of the transistors. When the P type transistor is adopted, the first electrode is a source electrode of the P type transistor, the second electrode is a drain electrode of the P type transistor, and when a low level signal is input into the gate electrode G, the source electrode and the drain electrode are electrically connected to each other; when the N type transistor is adopted, the first electrode is a source electrode of the N type transistor, the second electrode is a drain electrode of the N type transistor, and when a high level signal is input into the gate electrode G, the source electrode and the drain electrode are electrically connected to each other. In the embodiments of the present disclosure and the following description, as an example, the transistors in a pixel circuit are the P type transistors. Each transistor includes an active layer formed on a first semiconductor layer and a gate electrode formed on a first conductive layer, typically with only a gate insulating layer between the first semiconductor layer and the first conductive layer.

It should be noted that in the embodiment of the present disclosure, in addition to the 7TIC (i.e., seven transistors and one capacitor) structure shown in FIG. 3, the pixel driving circuit may alternatively have a structure including another number of transistors, such as a 7T2C structure, a 6TIC structure, a 6T2C structure, or a 9T2C structure, which is not limited in the embodiment of the present disclosure.

In the embodiment of the present disclosure, the display substrate includes a base substrate 101, and a pixel driving circuit and a light-emitting device sequentially disposed on the base substrate 101, and the pixel driving circuit includes a transistor, a capacitor, and a conductive signal line 1031. The transistor includes a bottom gate structure or a top gate structure. A gate electrode G of the transistor having the bottom gate structure is closer to the base substrate 101 than an active layer ACT, and the gate electrode G thereof may serve as a light shielding layer 10′ to protect a channel region in the active layer ACT; and a gate electrode G of the transistor having the top gate structure is farther from the substrate base 101 than an active layer ACT. When the transistors of the pixel driving circuit are formed on the base substrate 101, the bottom gate structure or the top gate structure may be employed, which is not specifically limited in the present disclosure. In the embodiments of the present disclosure and the following description, a transistor having a top gate structure will be described as an example.

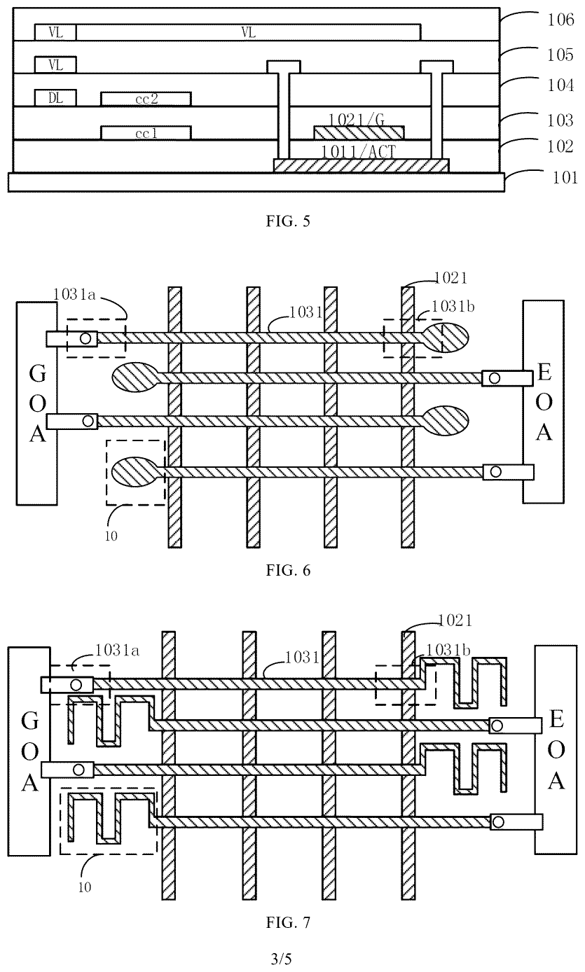

FIG. 5 is a cross-sectional view of a display substrate according to an embodiment of the present disclosure. As shown in FIG. 5, a first semiconductor layer 102, a first conductive layer 103, a second conductive layer 104, a third conductive layer 105, and a fourth conductive layer 106 are sequentially disposed on a base substrate 101. The first semiconductor layer 102 is used to form an active layer ACT of a transistor, and may be made of amorphous silicon, polysilicon, an oxide semiconductor material, or the like. The first semiconductor layer 102 may include a plurality of first semiconductor structures 1021, one of which may be used to form active layers ACT of all or a part of the transistors in one pixel driving circuit, and the active layers ACT of the first reset transistor T1, the second reset transistor T2, the data writing transistor T3, the driving transistor T4, the threshold compensation transistor T5, the first light-emitting control transistor T6, and the second light-emitting control transistor T7 may be formed on the first semiconductor layer 102. The first conductive layer 103 may include a first plate cc1 of the capacitor C, a first reset control signal line Rst1, a conductive signal line 1031, and gate electrodes G of the first reset transistor T1, the second reset transistor T2, the data writing transistor T3, the driving transistor T4, the threshold compensation transistor T5, the first light-emitting control transistor T6, and the second light-emitting control transistor T7, wherein the conductive signal line 1031 includes a scan signal line connected to the gate driving circuit GOA and an light-emitting control signal line connected to the light-emitting control driving circuit EOA, the scan signal line is configured to provide an electrical signal to the scan signal terminal Gate, and the light-emitting control signal line is configured to provide an electrical signal to the light-emitting control terminal EM. The second conductive layer 104 includes a second plate cc2 of the capacitor C and a power signal line VL. The third conductive layer 105 includes a power signal line VL and a data line DL configured to provide an electrical signal to the data signal terminal Data. The fourth conductive layer 106 includes power signal lines VL, which may cross each other. Insulating layers are formed between the conductive layers and between the conductive layer and the semiconductor layer. The above power signal lines VL include an initialization signal line connected to the initialization signal terminal Vint, a reset signal line connected to the reset signal terminal Reset, and a power voltage signal line configured to provide a power voltage.

The gate driving circuit GOA and the light-emitting control driving circuit EOA in the driving circuit are both composed of transistors and capacitors, and may be formed in the same layer as the transistors and capacitors in the pixel driving circuit during forming the gate driving circuit GOA and the light-emitting control driving circuit EOA. For example, the active layers ACT of the transistors in the gate driving circuit GOA and the light-emitting control driving circuit EOA are formed in the first semiconductor layer 102, and the gate electrodes G are formed in the first conductive layer 103; and the two plates of each capacitor are formed in the first conductive layer 103 and the second conductive layer 104, respectively. The transistors and the capacitors in the gate driving circuit GOA, the light-emitting control driving circuit EOA, and the pixel driving circuit are formed in the same layer, so that the manufacturing processes can be reduced.

It should be noted that the above structure is only an exemplary structure, and may be adjusted according to the actual structure of the display substrate or according to the specific structure of the pixel driving circuit, and is not limited in any further detail herein.

In a first aspect, an embodiment of the present disclosure provides a display substrate, which includes a base substrate 101, a first semiconductor layer 102 and a first conductive layer 103 stacked on the base substrate 101. The first conductive layer 103 includes a plurality of conductive signal lines 1031 extending in a first direction, and arranged side by side in a second direction; each conductive signal line 1031 has a first end 1031a electrically connected to the driving circuit and a second end 1031b. The first semiconductor layer 102 includes at least one first semiconductor structure 1021 extending along the second direction; an orthographic projection of each first semiconductor structure 1021 on the base substrate 101 overlaps with an orthographic projection of the second end 1031b of the at least one conductive signal line 1031 on the base substrate 101. The first semiconductor structure 1021 is a semiconductor pattern formed by using amorphous silicon, polysilicon, an oxide semiconductor material, or the like in the first semiconductor layer 102, and the first semiconductor structure 1021 is used for forming the active layers ACT of one or more transistors. The display substrate further includes an electrostatic discharge device 10 disposed on the base substrate 101, and electrically connected to the second end 1031b of the conductive signal line 1031, with the orthographic projection of the second end 1031b of the conductive signal line 1031 at least overlapping with the orthographic projection of the first semiconductor structure 1021 on the base substrate 101.

In the embodiment of the present disclosure, the conductive signal line 1031 includes at least one of the scan signal line and the light-emitting control signal line. When the conductive signal line 1031 includes the scan signal line, the driving circuit includes the gate driving circuit, and the first end 1031a of one scan signal line is connected to an output terminal of one first shift register in the gate driving circuit. When the conductive signal line 1031 include the light-emitting control signal line, the driving circuit includes the light-emitting control driving circuit, and the first end 1031a of one light-emitting control signal line is connected to an output terminal of one second shift register in the light-emitting control driving circuit. It is understood that the conductive signal line 1031 may also include other types of signal lines, such as, the power signal line, the data line and the like. When one end of the conductive signal line 1031 is in a floating state, the end in the floating state may be electrically connected to the electrostatic discharge device.

In the embodiment of the present disclosure, the conductive signal lines 1031 are formed on the first conductive layer 103, the first semiconductor structures 1021 are formed in the first semiconductor layer 102, and only one gate insulating layer is disposed between the conductive signal lines 1031 and the first semiconductor structures 1021. The second end 1031b of each conductive signal line 1031 is in a floating state, and a large amount of static electricity may be accumulated on the second end 1031b due to a tip effect, which may easily cause the first semiconductor structure 1021 at a position corresponding to the second end 1031b to be broken down by the static electricity. The second end 1031b of the conductive signal line 1031 is electrically connected to the electrostatic discharge device 10 for discharging the static electricity at the second end 1031b, for example, transferring the static electricity at the second end 1031b or preventing a large amount of static electricity from being accumulated due to the tip effect, so as to improve the yield of the display substrate and the reliability of the display product.

In some examples, FIG. 6 is a schematic diagram of a structure of a patch electrode as an electrostatic discharge device according to an embodiment of the present disclosure. FIG. 7 is a schematic diagram of a structure of a meandering line as an electrostatic discharge device according to an embodiment of the present disclosure. As shown in FIGS. 6 and 7, the electrostatic discharge device 10 and the conductive signal line 1031 electrically connected to each other have a one-piece structure. The electrostatic discharge device 10 and the conductive signal line 1031 are formed in the same first conductive layer 103. The electrostatic discharge device 10 includes a patch electrode or a meandering line. As shown in FIG. 6, when the electrostatic discharge device 10 is the patch electrode, the patch electrode is electrically connected to the second end 1031b of the conductive signal line 1031, and a shape of an orthographic projection of the patch electrode on the base substrate 101 is an ellipse or a circle, which enlarges an area of the orthographic projection of the second end 1031b on the base substrate 101 and reduces the risk that a large amount of static electricity accumulated on the second end 1031b due to a tip effect breaks down the first semiconductor structure 1021 close to the second end 1031b. As shown in FIG. 7, when the electrostatic discharge device 10 is the meandering line, the meandering line is electrically connected to the second end 1031b of the conductive signal line 1031, and extends away from the second end 1031b of the conductive signal line 1031. With such the structure, the position where a large amount of static electricity may be accumulated at the tip end extends from the second end 1031b away from the first semiconductor structure 1021. When a large amount of static electricity is accumulated at an end in a floating state of the meandering line, the first semiconductor structure 1021 is not broken down. It can be understood that an orthographic projection of the electrostatic discharge device 10 on the base substrate 101 does not overlap with the first semiconductor structure 1021 or other conductive structures.

It should be understood that the shape of the orthographic projection of the patch electrode on the base substrate 101 is ellipse because the ellipse shape does not include sharp corners. Alternatively, the orthographic projection of the patch electrode on the base substrate 101 may have other shapes, such as a polygonal shape with curved corners, or the like, and the patch electrode is formed to prevent the second end 1031b from being formed as the tip, which causes a large amount of static electricity to be accumulated at the tip. A shape of an orthographic projection of the meandering line on the base substrate 101 is a bent line or a wavy line, and the end of the meandering line in a floating state extends away from the second end 1031b and the first semiconductor structure 1021.

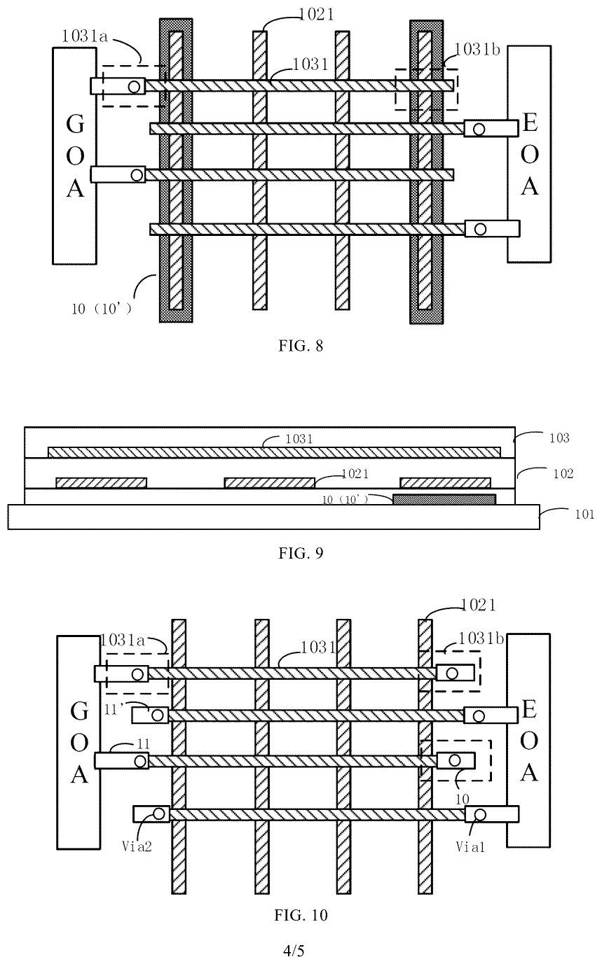

In some examples, FIG. 8 is a schematic diagram of a structure of a light shielding layer as an electrostatic discharge device according to an embodiment of the present disclosure. FIG. 9 is a schematic cross-sectional view of a light shielding layer as an electrostatic discharge device according to an embodiment of the present disclosure. As shown in FIGS. 8 and 9, the first conductive layer 103 is located on a side of the first semiconductor layer 102 away from the base substrate 101, and a light shielding layer 10′ which serves as the electrostatic discharge device 10 is disposed between the first semiconductor layer 102 and the base substrate 101. An orthographic projection of the light shielding layer 10′ on the base substrate 101 overlaps with the orthographic projection of the second end 1031b of the conductive signal line 1031 on the base substrate 101, and the light shielding layer 10′ is electrically connected to the second end 1031b in a coupling manner.

Further, the orthographic projection of the light shielding layer 10′ on the base substrate 101 overlaps an orthographic projection of the first semiconductor structure 1021 close to the second end 1031b on the base substrate 101. In the prior art, in generally, the light shielding layer 10′ is formed between the base substrate 101 and the first semiconductor layer 102, and is configured to shield light reflected from the base substrate 101 and preventing the reflected light from irradiating a channel region of the active layer ACT of the transistor, which may affect the function of the transistor. In the present disclosure, in order to form a capacitor by using the second end 1031b of the conductive signal line 1031, the light shielding layer 10′ completely overlaps the entire first semiconductor structure 1021, an edge of the orthographic projection of the light shielding layer 10′ on the base substrate 101 exceeds an edge of the orthographic projection of the first semiconductor structure 1021 on the base substrate 101, the light shielding layer 10′ is directly opposite to the second end 1031b of the conductive signal line 1031 without the first semiconductor structure 1021 therebetween, so that the electrical coupling can be realized, and the capacitor is formed. The light shielding layer 10′ completely covers or overlaps the entire first semiconductor structure 1021 and at least covers the first semiconductor structure 1021 closest to the second end 1031b, and a complicated patterning process is not required during manufacturing. the light shielding layer 10′ overlaps with the second end 1031b to form the capacitor, a voltage of the capacitor does not change suddenly. When a large amount of static electricity is generated at the second end 1031b instantaneously, since the second end 1031b and the light shielding layer 10′ form the capacitor, the static electricity at the second end 1031b does not directly cause the first semiconductor structure 1021 close to the second end 1031b to be broken down.

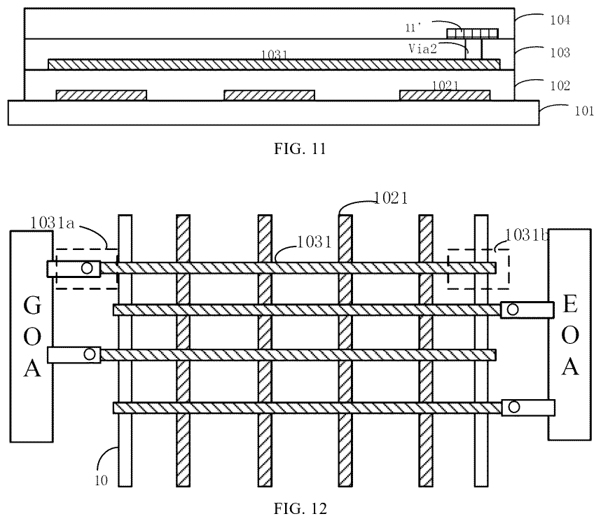

In some examples, FIG. 10 is a schematic diagram of a structure of a redundant first transfer line as an electrostatic discharge device according to an embodiment of the present disclosure. FIG. 11 is a schematic cross-sectional view of a redundant first transfer line as an electrostatic discharge device according to an embodiment of the present disclosure. As shown in FIGS. 10 and 11, a second conductive layer 104 is disposed on a side of the first semiconductor layer 102 away from the base substrate 101, and includes an output terminal of the driving circuit and a first transfer line 11 electrically connected to the output terminal. When the driving circuit is the gate driving circuit, the output terminal of the driving circuit is an output terminal of the first shift register, and when the driving circuit is the light-emitting control driving circuit, the output terminal of the driving circuit is an output terminal of the second shift register. The first transfer line 11 is electrically connected to the second end 1031b of the conductive signal line 1031 through a first connection via Vial. When the transistor has the top gate structure, the first conductive layer 103 is located between the first semiconductor layer 102 and the second conductive layer 104. When the transistor has the bottom gate structure, the first conductive layer 103 is located on a side of the first semiconductor layer 102 away from the second conductive layer 104. In the embodiments of the present disclosure, the transistor has the top gate structure as an example for illustration. The second conductive layer 104 includes the output terminal of the driving circuit and the first transfer line 11 for electrically connecting the output terminal of the driving circuit to the conductive signal line 1031, and the first transfer line 11 is electrically connected to the first end 1031a of the conductive signal line 1031 through the first connection via Via1.

Further, the second conductive layer 104 includes a redundant first transfer line 11′, which is not electrically connected to the driving circuit; the redundant first transfer line 11′ is electrically connected to the second end 1031b of the conductive signal line 1031 through a second connection via Via2; the redundant first transfer line 11′ serves as the electrostatic discharge device 10. By providing the redundant first transfer line 11′ electrically connected to the second end 1031 b of the conductive signal line 1031 through the second connection via Via2, the static electricity at the second end 1031b is transmitted to other layers, so that the static electricity is kept away from the first semiconductor structure 1021 in the first semiconductor layer 102, which is prone to be broken down.

In the embodiment of the present disclosure, the transistor has the top gate structure as an example for illustration. Therefore, the first conductive layer 103 is located between the first semiconductor layer 102 and the second conductive layer 104, a layer structure is disposed between the first conductive layer 103 and the second conductive layer 104, and the second connection via Via2 penetrates through the layer structure; wherein the layer structure at least includes an interlayer insulating layer. In addition to the interlayer insulating layer, other conductive layer and insulating layer structures may be further disposed between the first conductive layer 103 and the second conductive layer 104. For example, the third conductive layer 105 is formed between the first conductive layer 103 and the third conductive layer 105 by exchanging positions of the third conductive layer 105 and the second conductive layer 104. In this case, the second connection via Via2 needs to penetrate through the insulating layer and the third conductive layer 105. The static electricity transferred from the conductive signal line 1031 to the redundant first transfer line 11′ necessarily passes through the second connection via Via2 penetrating through the layer structure, and in this transferring process, the static electricity passes through the layers, which can reduce the amount of the static electricity to a certain degree.

It should be noted that in the embodiment of the present disclosure, the insulating layers are formed between the conductive layers and between the conductive layer and the semiconductor layer, and may be organic insulating layers or inorganic insulating layers, and are not shown in the drawings, and a material of the insulating layers is not limited in the embodiment of the present disclosure.

In a second aspect, an embodiment of the present disclosure provides a display substrate, as shown in FIGS. 8 and 9, which includes a base substrate 101, a first semiconductor layer 102 and a first conductive layer 103 stacked on the base substrate 101. The first conductive layer 103 includes a plurality of conductive signal lines 1031 extending in a first direction, and arranged side by side in a second direction; each conductive signal line 1031 has a first end 1031a electrically connected to the driving circuit and a second end 1031b. The first semiconductor layer 102 includes at least one first semiconductor structure 1021 extending along the second direction; an orthographic projection of the first semiconductor structure 1021 on the base substrate 101 overlaps with an orthographic projection of the second end 1031b of the at least one conductive signal line 1031 on the base substrate 101. The first semiconductor structure 1021 is a semiconductor pattern, which is used for forming the active layers ACT of one or more transistors, formed by using amorphous silicon, polysilicon, an oxide semiconductor material, or the like in the first semiconductor layer 102. The first conductive layer 103 is located on a side of the first semiconductor layer 102 away from the base substrate 101, and a light shielding layer 10′ which serves as the electrostatic discharge device 10 is disposed between the first semiconductor layer 102 and the base substrate 101, an orthographic projection of the light shielding layer 10′ on the base substrate 101 overlaps with the orthographic projection of the second end 1031b of the conductive signal line 1031 on the base substrate 101, and the light shielding layer 10′ is electrically connected to the second end 1031b in a coupling manner.

Further, the orthographic projection of the light shielding layer 10′ on the base substrate 101 covers or overlaps an orthographic projection of the first semiconductor structure 1021 close to the second end 1031b on the base substrate 101. In the prior art, the light shielding layer 10′ is in generally formed between the base substrate 101 and the first semiconductor layer 102, and is configured to shield light reflected from the base substrate 101 to prevent the reflected light from irradiating a channel region of the active layer ACT of the transistor, which may affect the function of the transistor. In the present disclosure, in order to form a capacitor by using the second end 1031b of the conductive signal line 1031, the light shielding layer 10′ completely covers the entire first semiconductor structure 1021, an edge of the orthographic projection of the light shielding layer 10′ on the base substrate 101 exceeds an edge of the orthographic projection of the first semiconductor structure 1021 on the base substrate 101, the light shielding layer 10′ is directly opposite to the second end 1031b of the conductive signal line 1031 without the first semiconductor structure 1021 therebetween, so that the electrical coupling can be realized, and the capacitor is formed. The light shielding layer 10′ completely covers the entire first semiconductor structure 1021 and at least covers the first semiconductor structure 1021 closest to the second end 1031b, and a complicated patterning process is not required during manufacturing. The overlapping portions of the light shielding layer 10′ and the second end 1031b (i.e., the portions of the light shielding layer 10′ and the second end 1031b where the light shielding layer 10′ overlaps with the second end 1031b) forms the capacitor, a voltage of the capacitor does not change suddenly. When a large amount of static electricity is generated at the second end 1031b instantaneously, since the second end 1031b and the light shielding layer 10′ form the capacitor, the static electricity at the second end 1031b does not directly cause the first semiconductor structure 1021 close to the second end 1031b to be broken down.

In a third aspect, an embodiment of the present disclosure provides a display substrate. FIG. 12 is a schematic diagram of a structure of an electrostatic discharge device disposed in a first semiconductor layer according to an embodiment of the present disclosure. As shown in FIG. 12, the display substrate includes a base substrate 101, a first semiconductor layer 102 and a first conductive layer 103 stacked on the base substrate 101. The first conductive layer 103 includes a plurality of conductive signal lines 1031 extending in a first direction, and arranged side by side in a second direction; each conductive signal line 1031 has a first end 1031a electrically connected to the driving circuit and a second end 1031b. The first semiconductor layer 102 includes at least one first semiconductor structure 1021 extending along the second direction; an orthographic projection of each first semiconductor structure 1021 on the base substrate 101 overlaps with an orthographic projection of the second end 1031b of the at least one conductive signal line 1031 on the base substrate 101. The first semiconductor structure 1021 is a semiconductor pattern, which is used for forming the active layers ACT of one or more transistors, formed by using amorphous silicon, polysilicon, an oxide semiconductor material, or the like in the first semiconductor layer 102. The electrostatic discharge device 10 is disposed in the first semiconductor layer 102 and on a side of the first semiconductor structure 1021 proximal to the second end 1031b of the conductive signal line 1031. The first semiconductor structure 1021 is usually made of polysilicon. The electrostatic discharge device 10 is disposed on a side of the first semiconductor layer 102 proximal to the second end 1031b than the first semiconductor structures 1021, an orthographic projection of the second end 1031b on the base substrate 101 overlaps with an orthographic projection of the electrostatic discharge device 10 on the base substrate 101, and the electrostatic discharge device is in a floating state. When a large amount of static electricity is accumulated on the second end 1031b of the conductive signal line 1031, the static electricity breaks down the electrostatic discharge device 10 rather than breaking down the first semiconductor structure 1021 for forming the active layers ACT of the transistors. It can be appreciated that the electrostatic discharge device 10 is not connected to any structure, and is formed as a sacrificial structure in the region of the first semiconductor structure 1021 closest to the second end 1031b of the conductive signal line 1031. The electrostatic discharge device 10 is arranged in a floating mode, which does not need to provide structures such as vias, thereby reducing the process difficulty.

Further, the material of the electrostatic discharge device 10 disposed in the first semiconductor layer 102 may be the same as the material of the first semiconductor structure 1021, and the first semiconductor material and the electrostatic discharge device 10 may be formed by using a same mask in a single step during manufacturing so that the electrostatic discharge device 10 is formed in the first semiconductor layer 102 without increasing the process and excessive cost.

In a fourth aspect, embodiments of the present disclosure further provide a display device, which includes the display substrate described in any one of the above embodiments. The display device may be any product with a display function, such as a mobile phone, a tablet computer, a television, a display, a notebook computer, a digital photo frame, a vehicle-mounted device, or the like, and may further be a wearable display device, such as a smart watch or the like. Other essential components of the display device are understood by one of ordinary skill in the art and are not described herein nor should they be construed as limiting the present disclosure.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and essence of the present disclosure, and such changes and modifications also fall within the scope of the present disclosure.

1. A display substrate, comprising a base substrate, and a first semiconductor layer and a first conductive layer stacked on the base substrate; wherein
the first conductive layer comprises a plurality of conductive signal lines extending in a first direction and arranged side by side in a second direction; and each of the conductive signal lines comprises a first end electrically connected to a driving circuit and a second end;
the first semiconductor layer comprises at least one first semiconductor structure extending along the second direction; and an orthographic projection of the first semiconductor structure on the base substrate overlaps with an orthographic projection of the second end of the at least one conductive signal line on the base substrate; and
the display substrate further comprises an electrostatic discharge device located on the base substrate and electrically connected to the second end of the conductive signal line, with the orthographic projection of the second end of the conductive signal line at least overlapping with the orthographic projection of the first semiconductor structure on the base substrate.

2. The display substrate of claim 1, wherein the electrostatic discharge device and the conductive signal line electrically connected to each other have a one-piece structure.

3. The display substrate of claim 2, wherein the electrostatic discharge device comprises a patch structure or a meandering line.

4. The display substrate of claim 3, wherein the electrostatic discharge device is the patch structure, and a shape of an orthographic projection of the patch structure on the base substrate comprises an ellipse.

5. The display substrate of claim 3, wherein the electrostatic discharge device is the meandering line extending away from the second end of the conductive signal line.

6. The display substrate of claim 1, wherein the first conductive layer is located on a side of the first semiconductor layer away from the base substrate, the display substrate further comprises a light shielding layer, serving as the electrostatic discharge device, between the first semiconductor layer and the base substrate; and an orthographic projection of the light shielding layer on the base substrate overlaps with the orthographic projection of the second end of the conductive signal line on the base substrate; and
the orthographic projection of the light shielding layer on the base substrate covers an orthographic projection of the first semiconductor structure close to the second end on the base substrate.

7. The display substrate of claim 1, further comprising a second conductive layer located on a side of the first semiconductor layer away from the base substrate and comprising an output terminal of the driving circuit and a first transfer line electrically connected to the output terminal, wherein the first transfer line is electrically connected to the first end of the conductive signal line through a first connection via.

8. The display substrate of claim 7, wherein the second conductive layer comprises a redundant first transfer line, serving as the electrostatic discharge device, electrically connected to the second end of the conductive signal line through a second connection via.

9. The display substrate of claim 1, wherein the plurality of conductive signal lines comprise at least one of a scan signal line and a light-emitting control signal line;
the plurality of conductive signal lines comprise the scan signal line, the driving circuit comprises a gate driving circuit, and a first end of one scan signal line is connected to an output terminal of one corresponding first shift register of the gate driving circuit; and
the plurality of conductive signal lines comprise the light-emitting control signal line, the driving circuit comprises a light-emitting control driving circuit, and a first end of one light-emitting control signal line is connected to an output terminal of one corresponding second shift register of the light-emitting control driving circuit.

10. The display substrate of claim 9, comprising a display region and a peripheral region; wherein the driving circuit comprises the gate driving circuit and the light-emitting control driving circuit located in the peripheral region and respectively arranged on two opposite sides of the base substrate in the display region along the first direction.

11. A display substrate, comprising a base substrate, and a first semiconductor layer and a first conductive layer stacked on the base substrate; wherein
the first conductive layer comprises a plurality of conductive signal lines extending in a first direction and arranged side by side in a second direction; and each of the conductive signal lines comprises a first end electrically connected to the driving circuit and a second end;
the first semiconductor layer comprises at least one first semiconductor structure extending along the second direction; and an orthographic projection of the first semiconductor structure on the base substrate overlaps with an orthographic projection of the second end of the at least one conductive signal line on the base substrate;
the first conductive layer is located on a side of the first semiconductor layer away from the base substrate, and the display substrate further comprises a light shielding layer, serving as an electrostatic discharge device, between the first semiconductor layer and the base substrate, and an orthographic projection of the light shielding layer on the base substrate overlaps with the orthographic projection of the second end of the conductive signal line on the base substrate, and
an orthographic projection of the light shielding layer on the base substrate covers an orthographic projection of the first semiconductor structure close to the second end on the base substrate.

12. A display substrate, comprising a base substrate, and a first semiconductor layer and a first conductive layer stacked on the base substrate; wherein
the first conductive layer comprises a plurality of conductive signal lines extending in a first direction and arranged side by side in a second direction; and each of the conductive signal lines comprises a first end electrically connected to the driving circuit and a second end;
the first semiconductor layer comprises at least one first semiconductor structure extending along the second direction; and an orthographic projection of the first semiconductor structure on the base substrate overlaps with an orthographic projection of the second end of the at least one conductive signal line on the base substrate; and
the display substrate further comprises an electrostatic discharge device located in the first semiconductor layer and located on a side of the first semiconductor structure proximal to the second end of the conductive signal line; an orthographic projection of the electrostatic discharge device on the base substrate overlaps with the orthographic projection of the second end of the conductive signal line on the base substrate, and the electrostatic discharge device is in a floating state.

13. A display device, comprising the display substrate of claim 1.
